(19) United States
(12) Patent Application Publication
(10) Pub. No.: US 2024/0201118 A1
(43) Pub. Date: Jun. 20, 2024

(54) SOIL PROBE

(71) Applicant: Krado Inc., Salt Lake City, UT (US)

(72) Inventors: Eric Andrew Lo, Salt Lake City, UT (US); Maxwell Wagner Ono, Maynard, MA (US); Jesse Linton Montgomery, Centerville, UT (US); Joaquin Fernandez, Walnut Creek, CA (US)

(73) Assignee: Krado Inc., Salt Lake City, UT (US)

(21) Appl. No.: 18/513,743

(22) Filed: Nov. 20, 2023

Related U.S. Application Data
(60) Provisional application No. 63/432,977, filed on Dec. 15, 2022.

(51) Int. Cl. G01N 27/22; H05K 1/18

(52) U.S. Cl. CPC G01N 27/223; G01N 27/226; G01N 27/228; H05K 1/181; H05K 2201/10098; H05K 2201/10151; H05K 2201/10189

(57) ABSTRACT

Described herein are soil probes designed to measure the moisture content of soil. Certain soil probes described herein involve capacitive sensing and comprise a pair of conductive layers (e.g., the top and bottom layers) of a multi-layer printed circuit board (PCB). To reduce variability and enhance the signal of soil moisture measurements, conductive inserts may be interposed between the soil and the PCB, so that the conductive inserts are in physical contact with the soil and are electrically coupled with the conductive layers of the PCB. Probes described herein can leverage the inexpensive nature of PCB-based moisture sensors with the corrosion resistance and/or mechanical strength of conductive inserts. The probe may be enclosed inside a housing to prevent intrusion of water, dust, and/or other contaminants.

### CROSS-REFERENCE TO RELATED APPLICATION

This application claims the benefit under 35 U.S.C. § 119(e) of U.S. Provisional Application Ser. No. 63/432,977, filed on Dec. 15, 2022, under Attorney Docket No. K0731.70000US00 and entitled “SOIL PROBE,” which is hereby incorporated herein by reference in its entirety.

### BACKGROUND

Various methods exist for measuring the moisture content of soil and other plant growing media. Some technologies are amenable to on-site monitoring such as time domain refractometry, frequency domain reflectometry, electrical conductivity, and surface tension. Solutions based on these technologies vary widely in accuracy and cost.

### SUMMARY OF THE DISCLOSURE

Some embodiments relate to a soil probe, comprising a soil penetrating portion comprising: a first printed circuit board (PCB) comprising a first conductive layer and a second conductive layer opposite the first conductive layer; and a first conductive insert electrically coupled to the first conductive layer of the first PCB, and a second conductive insert electrically coupled to the second conductive layer of the first PCB, wherein, when the soil penetrating portion is inserted in soil, both the first and second conductive inserts are configured to contact the soil.

In some embodiments, the soil probe further comprises circuitry electrically coupled to the first and second conductive layers of the first PCB and configured to determine a characteristic of the soil based on a signal appearing between the first and second conductive inserts.

In some embodiments, the circuitry is configured to determine a moisture content of the soil based on a measure of capacitance formed between the first and second conductive inserts. In some embodiments, the circuitry is mounted on the first PCB.

In some embodiments, the soil probe further comprises a second PCB coupled to the first PCB.

In some embodiments, the second PCB comprises a wireless transmitter.

In some embodiments, the second PCB is coupled to the first PCB via a Universal Serial Bus (USB) interface.

In some embodiments, the USB interface is a USB-C interface.

In some embodiments, the second PCB comprises a light sensor.

In some embodiments, the light sensor comprises a plurality of sensors, wherein each sensor of the plurality of sensors is configured to sense light at different wavelengths than other sensors of the plurality of sensors.

In some embodiments, the second PCB comprises a temperature sensor and/or a humidity sensor.

In some embodiments, the first conductive insert is in physical contact with the first conductive layer of the first PCB, and the second conductive insert is in physical contact with the second conductive layer of the first PCB.

In some embodiments, the first and second conductive inserts comprise aluminum, stainless steel and/or conductive polymer.

In some embodiments, the soil probe further comprises a first conductive component electrically coupling the first conductive insert with the first conductive layer of the first PCB, and a second conductive component electrically coupling the second conductive insert with the second conductive layer of the first PCB.

In some embodiments, the first and second conductive components comprise an epoxy resin.

In some embodiments, the soil probe further comprises a housing comprising the soil penetrating portion and a head portion coupled to the soil penetrating portion, wherein the first PCB is held by the soil penetrating portion of the housing.

In some embodiments, a second PCB is held by the head portion of the housing.

In some embodiments, the first and second conductive inserts are detachable from the soil penetrating portion.

In some embodiments, the first conductive insert has a thickness that is between 2 mm and 20 mm.

Some embodiments relate to a method for probing a soil using a soil probe comprising a first printed circuit board (PCB) and first and second conductive inserts, the method comprising: in response to the first and second conductive inserts contacting the soil, determining at least one characteristic of the soil based on a signal appearing between the first and second conductive inserts, wherein determining the characteristic of the soil comprises: transferring the signal from the first and second conductive inserts to first and second conductive layers positioned on opposite sides of the first PCB; and sensing the signal.

In some embodiments, determining the characteristic of the soil based on the signal appearing between the first and second conductive inserts comprises determining a moisture content of the soil based on a measure of capacitance formed between the first and second conductive inserts.

In some embodiments, determining the characteristic of the soil is performed using circuitry mounted on the first PCB.

In some embodiments, the method further comprises wirelessly transmitting information indicative of the characteristic of the soil to an electronic device outside the soil probe.

In some embodiments, wirelessly transmitting the information is performed using a wireless transmitter positioned on a second PCB coupled to the first PCB.

In some embodiments, the method further comprises transferring the information from the first PCB to the second PCB via a Universal Serial Bus (USB) interface.

In some embodiments, the USB interface is a USB-C interface.

In some embodiments, the information is transferred from the first PCB to the second PCB using an I2C communication protocol.

In some embodiments, the method further comprises sensing light using a light sensor positioned on the second PCB.

In some embodiments, sensing light using the light sensor comprises sensing light at a first wavelength using a first sensor; and sensing light at a second wavelength using a second sensor.

Some embodiments relate to a method for manufacturing a soil probe, comprising electrically coupling a first conductive insert to a first conductive layer of a first printed circuit board (PCB); electrically coupling a second conductive insert to a second conductive layer of the first printed circuit board (PCB), wherein the second conductive layer is positioned opposite the first conductive layer on the first PCB; and connecting the first and second conductive inserts to a soil penetrating portion so that, when the first and second conductive inserts are electrically coupled to the first and second conductive layers of the first PCB and the soil penetrating portion is inserted in a soil, the first and second conductive inserts are in contact with the soil.

In some embodiments, the method further comprises electrically coupling circuitry to the first and second conductive layers of the first PCB, the circuitry being configured to determine a characteristic of the soil based on a signal appearing between the first and second conductive inserts.

In some embodiments, the circuitry is configured to determine a moisture content of the soil based on a measure of capacitance formed between the first and second conductive inserts.

In some embodiments, electrically coupling the circuitry to the first and second conductive layers comprises mounting the circuitry to the first PCB.

In some embodiments, the method further comprises mounting a wireless transmitter on a second PCB, and coupling the second PCB to the first PCB.

In some embodiments, coupling the second PCB to the first PCB comprises connecting the second PCB to the first PCB via a Universal Serial Bus (USB) interface.

In some embodiments, the USB interface is a USB-C interface.

In some embodiments, electrically coupling the first conductive insert to the first conductive layer of the first PCB comprises placing the first conductive insert in physical contact with the first conductive layer of the first PCB, and electrically coupling the second conductive insert to the second conductive layer of the first PCB comprises placing the second conductive insert in physical contact with the second conductive layer of the first PCB.

In some embodiments, electrically coupling the first conductive insert to the first conductive layer of the first PCB comprises placing a first conductive component between the first conductive insert and the first conductive layer of the first PCB, and electrically coupling the second conductive insert to the second conductive layer of the first PCB comprises placing a second conductive component between the second conductive insert and the second conductive layer of the first PCB.

In some embodiments, the first and second conductive components comprise an epoxy resin.

### BRIEF DESCRIPTION OF THE DRAWINGS

Various aspects and embodiments of the devices and methods disclosed in the application will be described with reference to the following figures. It should be appreciated that the figures are not necessarily drawn to scale, nor do the figures necessarily illustrate all features and components of a working device, or are all illustrated features and components necessarily required to be present in all embodiments. Items appearing in multiple figures are indicated by the same reference number in the figures in which they appear.

FIG. 1A is a perspective view of a soil probe, in accordance with some embodiments;

FIG. 1B is an exploded perspective view of the soil probe of FIG. 1A, in accordance with some embodiments;

FIG. 2A is a schematic diagram of a portion of the soil probe of FIG. 1A, in accordance with some embodiments;

FIG. 2B is another schematic diagram of a portion of the soil probe of FIG. 1A, in which the conductive inserts are electrically coupled to the conductive layers of a printed circuit board, in accordance with some embodiments;

FIG. 2C is another schematic diagram of a portion of the soil probe of FIG. 1A, in which the conductive inserts are electrically coupled to the conductive layers of a printed circuit board via conductive components, in accordance with some embodiments;

FIG. 2D is a block diagram of the soil probe of FIG. 1A, in accordance with some embodiments;

FIG. 3A is a plot illustrating a representative reading of the soil probe as a function of soil moisture and in the presence of conductive inserts, in accordance with some embodiments;

FIG. 3B is a plot illustrating a representative reading of the soil probe as a function of soil moisture and in the absence of conductive inserts, in accordance with some embodiments;

FIG. 4 is a histogram comparing the standard deviation associated with the measured soil moisture obtained using a soil probe not including conductive inserts and using a soil probe including conductive inserts, in accordance with some embodiments;

FIG. 5A is a block diagram illustrating an example of a light sensor, in accordance with some embodiments; and

FIG. 5B is a plot illustrating a representative reading of the light sensor of FIG. 5A as a function of photosynthetic photon flux density (PPFD), in accordance with some embodiments.

### DETAILED DESCRIPTION

### I. Overview

Soil probes for measuring one or more characteristics (e.g., moisture content, conductivity, pH) of soil and other plant growing media based on capacitive sensors are disclosed. Certain soil probes described herein can improve upon conventional implementations in that they provide low cost and robustness, without sacrificing, and in some cases improving, accuracy and/or reproducibility, when compared to typical conventional commercially competitive soil probes for similar applications. Certain examples of the probes described herein are particularly suitable for residential applications, community gardens and agricultural applications in which high-end, costly equipment is out of reach. Certain of these and/or other advantages can be achieved by forming capacitive sensors using a combination of printed circuit boards (PCBs) and conductive inserts. More specifically, the probes disclosed in certain examples comprise a pair of conductive layers (e.g., the top and bottom layers) of a multi-layer PCB. Use of a PCB can reduce hardware costs relative to many conventional capacitive sensors in that signal transduction and processing can occur on the same PCB without the added expense and engineering constraints that are required when electrode signals are mediated through connectors. Additionally, PCBs are generally inexpensive and have a significant cost advantage over other electrode materials that are used in capacitance soil sensing technology. However, typical conventional PCB-based capacitive sensors lack sufficient strength and resistance to corrosion for long-term and/or repetitive insertion in soil. Lack of strength may result in cracks in the PCB. Susceptibility to corrosion negatively affects the reliability of these types of conventional capacitive sensors as well as their lifetime. In certain examples of the capacitive sensors presently disclosed, these problems are addressed at least in part by interposing conductive inserts between the PCB and the soil. In this way, instead of placing the delicate PCB in contact with the soil, more mechanically robust conductive inserts may be positioned to penetrate and be placed in contact with the soil.

This approach can in some cases provide a variety of benefits over certain conventional implementations. First, the material and the shape of a conductive insert can be chosen to be more mechanically resistant and/or less susceptible to corrosion than what is possible on a layer of a PCB. Conductive inserts can allow for greater thicknesses than PCBs, which are commonly thin. For example, the thickness of a conductive insert may be 2 mm or more (e.g., from 2 mm to 20 mm, from 2 mm to 15 mm, from 2 mm to 10 mm, from 2 mm to 8 mm, from 2 mm to 6 mm, from 2 mm to 4 mm, from 2 mm to 3 mm, from 5 mm to 20 mm, from 5 mm to 15 mm, from 5 mm to 10 mm, from 5 mm to 8 mm, from 5 mm to 6 mm, from 8 mm to 20 mm, from 8 mm to 15 mm, from 8 mm to 10 mm). For comparison, the thickness of a common PCB is 1.6 mm. As a result, conductive inserts may be more mechanically resistant than PCBs. This makes the probes described herein more resistant than conventional probes to repeated insertion in soil. The additional mechanical resistance is particularly useful for insertion in hard soil. Further, fabrication of conductive inserts provides more material options than what is generally practical (or possible) with the conductive layers of a PCB. For example, conductive inserts may be made of materials that are more corrosion-resistant than the materials with which common PCBs are made (e.g., copper). Examples of such materials include aluminum and stainless steel or other passivated materials, which provide greater resistance to corrosion than copper, the material conventionally used for the conductive layers of a PCB.

Second, the conductive inserts described herein may be detachable and/or interchangeable, thus allowing a user to replace a corroded conductive insert with a new conductive insert without having to dispose of the entire probe. This extends the lifetime of the probe beyond what would be possible with conventional implementations. Third, interposing conductive inserts between the soil to be probed and the PCB may enhance the sensitivity to moisture and/or may reduce the variability of soil moisture measurements, thus improving accuracy. The increase in sensitivity may be due at least in part to an increase in the electric field in the area surrounding the probe owing to the greater conductive mass afforded by the conductive inserts. The increased electric field may render the probe less sensitive to soil heterogeneity, resulting in a higher sensitivity to moisture and less measurement variability.

Accordingly, certain examples of the disclosed probes are able to leverage the inexpensive nature of PCB-based capacitive sensors with the mechanical strength and corrosion-resistant nature of conductive inserts described herein. In some embodiments, a probe includes a pair of conductive inserts configured for contact with the soil, the conductive inserts being electrically coupled to a pair of conductive layers of a PCB (e.g., top and bottom layers). Electrical coupling between the conductive inserts and the conductive layers of a PCB may be performed through physical contact or by interposing a conductive component (e.g., a conductive film comprising a conductive adhesive, such as an epoxy resin). A sensor may determine a characteristic (e.g., moisture content) of the soil sample based on a measure of capacitance. The sensor may be mounted on the same PCB hosting the conductive layers. In some embodiments, a probe includes a second PCB on which are mounted other electronic components, including but not limited to a wireless transmitter and/or other types of sensors (e.g., temperature, humidity, etc.). The probe may be designed so that, when the probe is inserted in soil, the first PCB is below the soil surface (at least partially) and the second PCB is above the soil surface (at least partially). This allows the first PCB to perform measurements of the soil and the second PCB to perform other operations without interference due to the soil.

The probes described herein may be used in a variety of contexts, including in domestic (e.g., indoor and/or outdoor house plants/garden) and commercial agricultural and/or landscape applications, as well as in community gardens, among other applications. In one example, a probe of the types described herein may be deployed in domestic applications to monitor the health of a plant and/or the environment surrounding the plant. Software applications may allow users to interface with the probe, which may generate reports regarding one or more characteristics of the soil (e.g., moisture content) and/or any information (e.g., related to the health of the plant or the surrounding environment) that can be derived from the soil, from the plant and/or from the surrounding environment. Using the information provided from the probe, the user may decide what (if any) action to take—e.g., provide more water, change nutrients, use fertilizers, replant, etc. In another example, a probe of the types described herein may be deployed in agricultural applications to monitor the health of a crop and/or the surrounding environment. In yet another example, a probe of the types described herein may facilitate seed germination in potted plants and/or trees.

Moisture content may be quantified in any suitable way known to those of ordinary skill in the art. In one example, moisture content may be quantified as a percentage of weight of moist soil (e.g., weight of water content divided by total weight of a soil sample of a predefined volume). In another example, moisture content may be quantified as a percentage of volume (e.g., volume of water content divided by a predefined volume of a soil sample). It should be further noted that the soil probe described herein may be used (in addition to, or in alternative to, quantifying moisture content) to quantify other characteristics, including but not limited to the conductivity of the soil and/or the pH of the soil. Such other characteristics may be detected using the same capacitive sensor used to quantify soil moisture, or using other types of sensors mounted on the soil probe.

### II. Exemplary Soil Probes

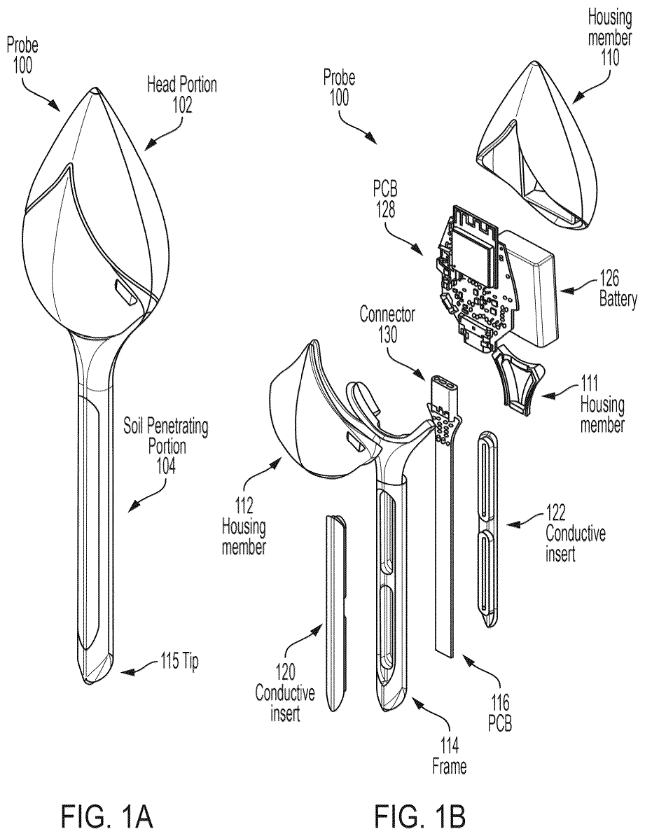

FIG. 1A is a perspective view and FIG. 1B is an exploded perspective view of a soil probe, in accordance with some embodiments. As shown in FIG. 1A, soil probe 100 may have a head portion 102 and a soil penetrating portion 104. Soil penetrating portion 104 is configured for insertion in soil or other plant growing media. For example, soil penetrating portion 104 may be elongated along one axis. In some embodiments, soil penetrating portion 104 has a generally cylindrical shape (though other shapes are also possible). Optionally, to facilitate insertion in soil, soil penetrating portion 104 has a sharp, pointed or tapered tip 115. Head portion 102 may be configured to stay (at least partially) above the soil surface when the probe is inserted in soil.

As further shown in FIG. 1B, probe 100 may include two distinct PCBs-PCB 116 and PCB 128. However, single-PCB implementations are also possible. When soil penetrating portion 104 is inserted in soil, one PCB (116) may be configured to be at least partially below the soil surface and one PCB (128) may be configured to stay at least partially above the soil surface. As a result, PCB 116 may be used to sense one or more characteristics (e.g., moisture content, conductivity, pH) of the soil and PCB 128 may be used to perform other operations (e.g., sensing of other environmental quantities—such as light intensity, oxygen concentration, carbon dioxide concentration, relative humidity, air temperature, etc., data and/or signal processing, wireless transmission, etc.) without being affected by submersion in the soil. In some embodiments, PCBs 116 and 128 are electrically coupled to each other using a Universal Serial Bus (USB) interface (e.g., a USB-C interface). Other interfaces are also possible, including Thunderbolt, Lightning, HDMI, and DisplayPort.

In some embodiments, probe 100 includes multiple pieces forming a housing, though single-piece housings are also possible. The housing may enclose the PCBs to prevent intrusion of water, dust, or other contaminants. The housing may include housing members 110, 111 and 112 and frame 114, which in some embodiments are made of an electrically insulating material (e.g., plastic). In certain embodiments, one or more of housing members 110, 111 and 112 and frame 114 may be manufactured by three-dimensional (3D) printing. When attached to each other (for example by interference fit, clips, detents, solvent bonding, screws, bolts, glue, etc.) housing members 110 and 112 define a cavity. In some embodiments the joints are waterproof, thereby sealing the cavity. Printed circuit board (PCB) 128 and battery 126 may be associated with head portion 102. For example, PCB 128 and battery 126 may be attached to one or more housing members (directly by interference fit, clips, detents, solvent bonding, screws, bolts, glue, or indirectly through other intermediate components), may be held by the housing members, or may be otherwise disposed in the cavity defined by the housing members. Battery 126 powers the operation of PCB 128. Battery 126 may be rechargeable in some embodiments, and/or may include lithium-based cells. As described in further detail below, PCB 128 may include various electronic components, including but not limited to a processor, a memory, a wireless transceiver and one or more sensors. In this example, head portion 102 is shaped so that PCB 128 and battery 126 stay above the soil surface when soil penetrating portion 104 is inserted into soil. For example, head portion 102 may be wider than soil penetrating portion 104 with respect to either one (or both) of the axes perpendicular to the direction of insertion. In this way, head portion 102 provides additional resistance against soil penetration when the probe is pressed into the soil. Having at least a portion of head portion 102 above the soil surface may ensure proper operation of the electronic components of PCB 128.

In some embodiments, soil penetrating portion 104 includes a frame 114, which may be made of an electrically insulating material (e.g., plastic). An upper part of frame 114 may be shaped for connection to head portion 102 (e.g., housing members 110 and 112). PCB 116 may be held by frame 114 or may be attached to it (directly by interference fit, clips, detents, solvent bonding, screws, bolts, glue, or indirectly through other intermediate components). As discussed in further detail below, PCB 116 may include two or more conductive layers. PCB 116 may have a substrate made of a rigid material (e.g., FR-4).

Conductive inserts 120 and 122 form a capacitive sensor configured to sense a characteristic (e.g., moisture content) of the soil. Conductive inserts 120 and 122 are part of soil penetrating portion 104. As a result, when soil penetrating portion 104 is inserted in soil, at least a portion of conductive insert 120 and at least a portion of conductive insert 122 are in physical contact with the soil. Conductive inserts 120 and 122 may be held by frame 114 or may be attached to it (directly by interference fit, clips, detents, screws, bolts, or indirectly through other intermediate components). Conductive inserts 120 and 122 may be attached to the housing in a way that enables ease of replacement (e.g., by interference fit, clips, detents, screws, bolts, or indirectly through other intermediate components). In this way, a user may easily replace a corroded conductive insert with a new one when necessary. Conductive insert 120 may be electrically coupled to a first conductive layer of PCB 116 (whether via physical contact or through an intermediate conductive component, such as an intermediate conductive component). Similarly, conductive insert 122 may be electrically coupled to a second conductive layer of PCB 116 (again, whether via physical contact or through an intermediate conductive component, such as an intermediate conductive component). In some embodiments, at least a portion of PCB 116 may be below the soil surface when soil penetrating portion 104 is inserted in soil.

Conductive inserts 120 and 122 may be made of conductive materials that are more suitable to contact with soil than the conductive layers of PCB 116. For example, conductive inserts 120 and 122 may be made of conductive materials that are more resistant to abrasion and/or corrosion than the conductive layers of PCB 116. In some embodiments, conductive inserts 120 and 122 comprise one or more metals and/or one or more electrically conductive polymers (e.g., a polymer doped with carbon black, graphite, and/or a metal). Non-limiting examples of suitable metals include aluminum, stainless steel, silver, gold, platinum, nickel, chromium, and alloys thereof. Conductive epoxy may be used in some embodiments. Conductive inserts 120 and 122 may have a higher mechanical strength than the conductive layers of PCB 116, which are commonly made of copper. In some embodiments, a conductive insert has a mechanical characteristic (e.g., a Young's modulus, shear modulus, bulk modulus, stiffness, tensile strength, compressive strength) that is at least 2 times, at least 3 times, at least 4 times, at least 5 times, at least 10 times, at least 20 times, or at least 50 times higher than the mechanical characteristic of a conductive layer of a PCB electrically coupled to the conductive insert.

Connector 130 may place PCB 116 in electrical communication with PCB 128. In the example of FIG. 1B, the male connector is mounted to PCB 116 and the female connector is mounted to PCB 128. However, the opposite arrangement is also possible. Connector 130 may be designed in accordance with the USB protocol (e.g., USB-C), though other types of connectors are also possible, including but not limited to Thunderbolt, Lightning, HDMI and DisplayPort. The widespread availability of USB-C connectors may remove the need for specialized cables in some circumstances, making these types of connectors particularly attractive for the PCBs described herein. The types of connectors described above may be used for PCB-PCB communication as described above and/or for communication between a PCB of the probe and an external computer. Housing member 111 may be shaped to cover at least a portion of connector 130. Connector 130 may permit transfer of data from PCB 116 to PCB 128 (and vice versa), including information obtained using capacitive sensor(s) on PCB 116.

In some embodiments, connector 130 supports an I2C communication protocol, which enables simplicity and low manufacturing costs. 12C signals may be routed over sideband (SBU) pins of a USB-C connector, for example. The USB Type-C specification allows re-purposing of these signals for alternate uses such as audio adapters, Display Port, HDMI, etc. Power delivery (PD) handshaking or complier (CC) line configuration, which are sometimes used to enable these standards, may not be implemented in some embodiments. First, the mechanical design of the soil probe may prevent direct insertion into a USB-C port of a personal computer. Second, the head portion of a soil probe (which could be connected to a standard USB-C cable during charging) may not activate I2C pins until probe connection is detected.

Soil probe 100 may have any suitable length. In some embodiments, the soil probe has a length of 1 m or less, 0.8 m or less, 0.6 m or less, 0.5 m or less, 0.4 m or less, 0.35 m or less, 0.3 m or less, 0.25 m or less, 0.2 m or less, 0.15 m or less, 0.1 m or less, 0.08 m or less, 0.06 m or less, or 0.04 m or less. In certain embodiments, the soil probe has a length in a range from 0.04 m to 1 m, 0.04 m to 0.5 m, 0.04 m to 0.1 m, 0.08 m to 1 m, 0.08 m to 0.5 m, 0.08 m to 0.1 m, 0.1 m to 1 m, 0.1 m to 0.5 m, or 0.5 m to 1 m.

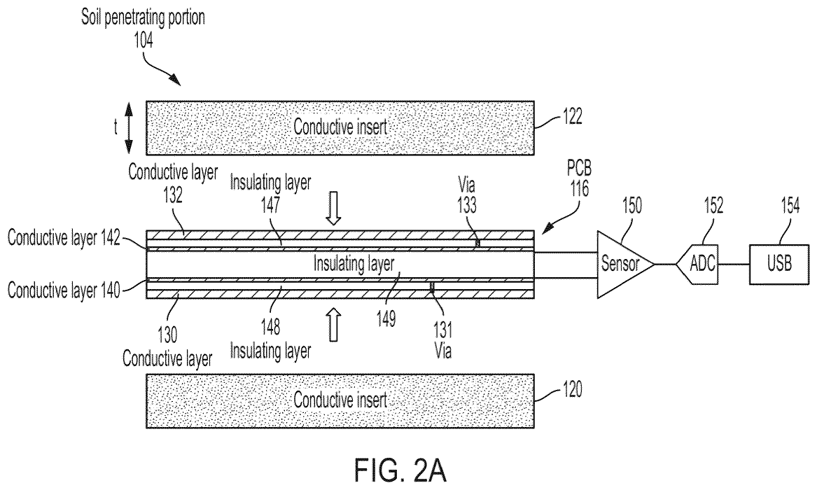

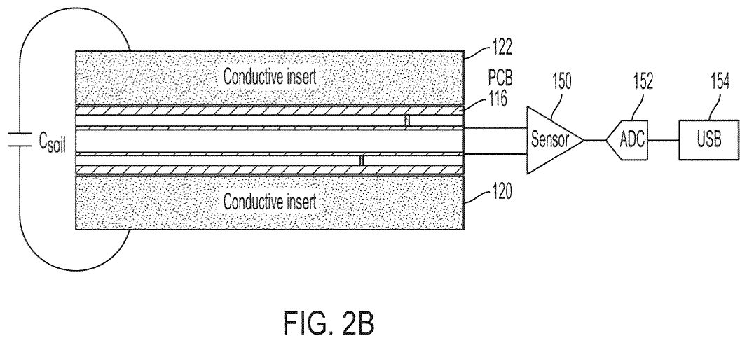

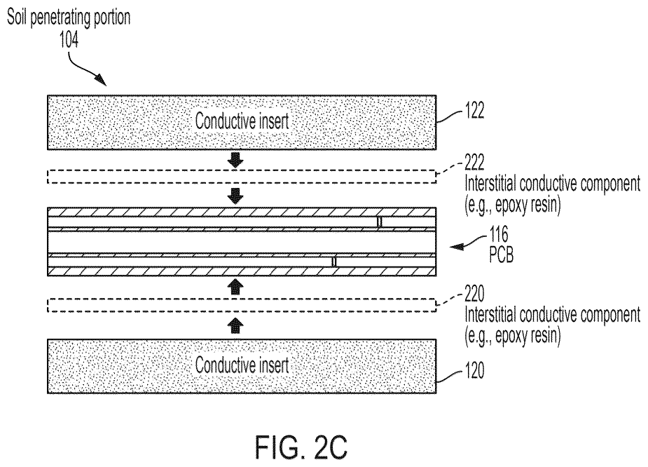

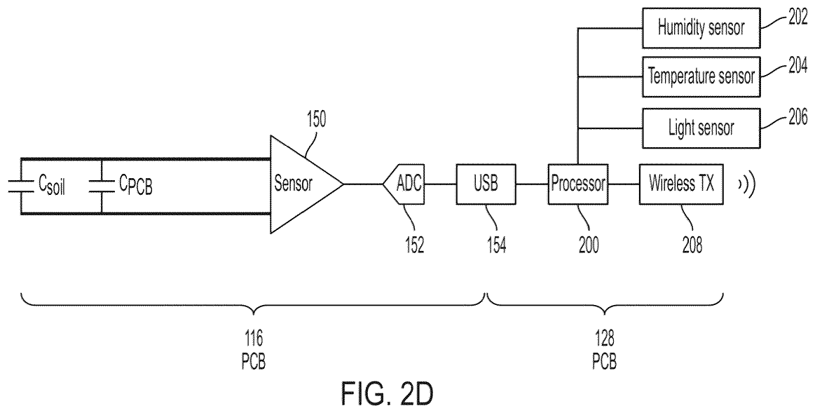

FIGS. 2A-2B are schematic diagrams illustrating certain components of the soil penetrating portion of the soil probe of FIG. 1A, in additional detail. In the depiction of FIG. 2A, conductive inserts 120 and 122 are disconnected from PCB 116. In the depiction of FIG. 2B, conductive inserts 120 and 122 are electrically coupled to PCB 116 via direct physical contact. When conductive inserts 120 and 122 are electrically coupled to PCB 116 and the soil penetrating portion 104 is inserted in soil, a capacitor Cₛₒᵢₗ is formed between conductive inserts 120 and 122 that passes through the soil. Thus, the conductive inserts form a soil moisture capacitive sensor that relies on soil to act as the dielectric element. The capacitance of Cₛₒᵢₗ is proportional to the dielectric constant of the surrounding soil sample. Because changes in water concentration cause changes in dielectric constant, changes in capacitance are directly related to the moisture content of the soil sample.

With reference to FIG. 2A, soil penetrating portion 104 includes conductive inserts 120 and 122 and PCB 116. PCB 116 in the illustrated example includes multiple conductive layers 130, 132, 140, 142 stacked on top of one another and held together by alternating insulating layers 147, 148 and 149. The outer layers of the PCB (130 and 132) may be conductive, thus permitting electrical coupling with conductive inserts 120 and 122 (through physical contact or using intermediate components, such as intermediate conductive components, not shown in FIG. 2A). PCB 116 may further include inner conductive layers (140 and 142) configured to route signals across the board as needed. In the example of FIG. 2A, via 133 electrically couples conductive layers 132 and 142 together, and via 131 electrically couples conductive layers 130 and 140 together.

As further shown in FIG. 2A, probe 100 may further include a sensor 150, an analog-to-digital converter (ADC) 152 and a USB interface 154 (though other types of interfaces are also possible such as Thunderbolt and Lightning). In some embodiments, one or more among sensor 150, ADC 152 and USB interface 154 may be part of soil penetrating portion 104. For example, one or more among sensor 150, ADC 152 and USB interface 154 may be disposed on PCB 116. Sensor 150 may be configured to sense the capacitance of the capacitive sensor. In some embodiments, sensor 150 may estimate the volumetric water content of soil by indirectly measuring the dielectric constant of the surrounding medium. Because the dielectric constant of dry soil (typically between 2 and 6) is significantly lower than that of water (about 78.4), small changes in moisture content result in measurable changes in dielectric constant. In a capacitive circuit comprising two electrodes separated by a dielectric medium, the dielectric constant is a function of the capacitance and the geometry of the electrodes and the dielectric medium (e.g., whether the electrodes are placed opposite the dielectric medium or coplanar on one side of the dielectric medium). The soil moisture capacitive sensors described herein approximate a capacitor circuit having two electrodes that utilize the surrounding soil as the dielectric medium.

In some embodiments, sensor 150 may estimate the dielectric constant of the surrounding medium based on a measurement of resonant frequency. It is known that the total capacitance of a system (Ct) can be related to the resonant frequency F of a system based on the following expression:

$$F = \frac{1}{2 π \sqrt{L {C}_{t}}}$$

where L represents the inductance of the system. Sensor 150 may use various methods to measure the resonant frequency F. For example, one method involves passing a square wave through the capacitor and measuring the decay rate of the output voltage. Sensor 150 may determine the capacitance Ct from the measured resonant frequency using the above-identified equation. Based on the capacitance Ct and the geometry of the capacitor, sensor 150 may determine the dielectric constant of the surrounding medium. Based on the dielectric constant of the surrounding medium, sensor 150 may determine moisture content. In some embodiments, a mathematical model may be used to convert the measured resonant frequency to the dielectric constant. The model may rely on parameters calculated using a calibration procedure. The model may involve fitting an equation using the previously calculated parameters and the measured resonant frequency.

ADC 152 may then digitize the signal generated using sensor 150. USB interface 154 may transfer the digitized information to other electronic components of probe 100 for further processing, as described in detail further below.

In some embodiments, sensor 150 may determine other characteristics of the soil, in addition (or alternatively) to moisture content, including but not limited to the conductivity of the soil and/or the pH of the soil. Determination of conductivity and/or pH may be performed on the basis of a signal appearing between conductive inserts 120 and 122.

The thickness of a conductive insert (“t”, represented in FIG. 2A) may be 2 mm or more (e.g., from 2 mm to 20 mm, from 2 mm to 15 mm, from 2 mm to 10 mm, from 2 mm to 8 mm, from 2 mm to 6 mm, from 2 mm to 4 mm, from 2 mm to 3 mm, from 5 mm to 20 mm, from 5 mm to 15 mm, from 5 mm to 10 mm, from 5 mm to 8 mm, from 5 mm to 6 mm, from 8 mm to 20 mm, from 8 mm to 15 mm, from 8 mm to 10 mm). Having a thicker conductive insert than what may be practical (or possible) with a PCB may increase the mechanical resistance of the probe, making it more resistant to repeated insertion in soil.

The arrangement of FIG. 2C differs from the arrangement of FIG. 2A in that interstitial conductive components 220 and 222 are interposed between the conductive inserts and the corresponding conductive layers of the PCB. Thus, the interstitial conductive components facilitate electrical coupling between the conductive inserts and the conductive layers. The interstitial conductive components may be made of any electrically conductive material. In certain embodiments, the interstitial conductive components comprise a conductive adhesive (e.g., a conductive epoxy resin, a conductive silicone resin, a conductive polyurethane resin). Interposing an interstitial conductive component between a conductive insert and a PCB may promote greater mechanical contact, thus reducing contact resistance. For example, an interstitial conductive component may fill gaps otherwise present between a conductive insert and a PCB. Interstitial conductive components of the types described herein may be made of solidified material (e.g., solidified epoxy) or fluid (e.g., using only part A or only part B of a conductive epoxy without mixing them together). In certain embodiments, the interstitial conductive components comprise one or more metals, e.g., metal films. Non-limiting examples of suitable metals include aluminum, copper, silver, gold, platinum, nickel, chromium, and alloys thereof. In some cases, the interstitial conductive components are formed from a different material than the conductive inserts. In some cases, the interstitial conductive components are formed from the same material as the conductive inserts. The interstitial conductive components may have any suitable geometry (e.g., shaped as a film or a mesh) and any suitable dimensions. In certain embodiments, conductive component 220 and/or conductive component 222 have a thickness of about 5 mm or less, 2 mm or less, 1 mm or less, or 500 μm or less. In certain embodiments, interstitial conductive component 220 and/or interstitial conductive component 222 have a thickness of at least 500 μm, at least 1 mm, at least 2 mm, or at least 5 mm. Combinations of these ranges are also possible (e.g., 500 μm to 5 mm, 1 mm to 5 mm).

FIG. 2D is a block diagram of the soil probe of FIG. 1A, in accordance with some embodiments. In this example, some of the components of the probe are disposed on PCB 116, while other components are disposed on PCB 128. As described in connection with FIG. 2A, PCB 116 may include sensor 150 and ADC 152. Sensor 150 may be coupled to the capacitor formed between the conductive inserts 120 and 122 (Cₛₒᵢₗ). An additional capacitor (C_{PCB})—representing the capacitance associated with the PCB—may appear in parallel with Cₛₒᵢₗ. In some embodiments, the capacitance of capacitor C_{PCB} may be determined using a calibration procedure. In this way, the capacitance of capacitor C_{PCB} may be discounted from the measure of capacitance performed using sensor 150.

PCB 128 may include a processor 200 (which may in turn include a memory), a wireless transmitter (TX) 208, and one or more sensors coupled to the processor. In the illustrated example, PCB 128 includes a humidity sensor 202, a temperature sensor 204 and a light sensor 206. In certain embodiments, one or more (or, in some cases, all) of humidity sensor 202, temperature sensor 204, and/or light sensor 206 may not be present. Sensors for measuring oxygen concentration and/or carbon dioxide concentration may be used in some embodiments. The components of PCB 116 may be placed in communication with the components of PCB 128 via USB (e.g., USB-C) interface 154 (though other types of interfaces are possible). Processor 200 may determine one or more characteristics (e.g., moisture content) of the soil surrounding the soil penetrating portion 104 using the digital signal provided from ADC 152. For example, processor 200 may have access to a look-up table (LUT) populated with pairs of values mapping the measured quantity to moisture content. Alternatively, processor 200 may be programmed to execute computer instructions configured to run a predefined mathematical relationship tying the measured quantity to moisture content. Information indictive of the measured moisture content may be transmitted outside probe 100 using wireless TX 208, which may be implemented based on the IEEE 802.11 standard (Wi-Fi), the Bluetooth standard, or other suitable standards. The information may be transmitted to a user's smartphone, smartwatch, tablet, or laptop, for example.

Probe 100 may be equipped with other sensors to monitor the surrounding environment. Humidity sensor 202 may sense the humidity of the surrounding environment. Temperature sensor 204 may sense the temperature of the surrounding environment. Light sensor 206 may sense the amount of ambient light, e.g., the photosynthetic photon flux density (PPFD). Examples of light sensors are described below. Information sensed by the sensors may be transmitted using wireless TX 208 so that the user may take measures when deemed appropriate (e.g., by repositioning the plant closer to a window, adjusting thermostat settings, and/or placing a humidifier in proximity to the plant). In some embodiments, placing the sensors and the wireless TX on a PCB other than the PCB involved with the detection of Cₛₒᵢₗ may ensure that the sensors and the wireless TX lie above the soil surface. In this way, the environmental quantities may be sensed more accurately, and wireless transmission may be performed while limiting soil attenuation.

Not all embodiments of the soil probe are limited to the arrangement of FIG. 2D. In some embodiments, some of the components illustrated in FIG. 2D as being disposed on PCB 116 may be disposed, instead or in addition, on PCB 128 and/or some of the components illustrated in FIG. 2D as being disposed on PCB 128 may, instead or in addition, be disposed on PCB 116. For example, processor 200 and/or wireless transmitter 208 and/or humidity sensor 202 and/or temperature sensor 204 and/or light sensor 206 may be disposed on PCB 116. In some embodiments, one or more components may be omitted. In some embodiments, probe 100 may be implemented using a single PCB. In such embodiments, USB interface 154 may be omitted and the components illustrated in FIG. 2D may be disposed on the same PCB. A bottom portion of the common PCB may be embedded inside soil penetrating portion 104 (thereby allowing detection of moisture content in the soil) and a top portion of the common PCB may be embedded inside head portion 102 (thereby allowing wireless transmission with low soil attenuation and/or sensing of environmental quantities such as temperature and ambient light).

### III. Examples of Measurements

In some embodiments, a method for soil characterization involves inserting soil penetrating portion 104 in soil. This may result in the first and second conductive inserts contacting the soil, thus forming a capacitor Cₛₒᵢₗ, the capacitance of which depends (among other parameters) upon at least one characteristic (e.g., moisture content) of the soil surrounding soil penetrating portion 104. In response to the first and second conductive inserts contacting the soil, processor 200 may determine at least one characteristic (e.g., moisture content) of the soil based on a signal appearing between the first and second conductive inserts (e.g., based on a measure of capacitance formed between the first and second conductive inserts). Determining the characteristic of the soil may involve: i) transferring the signal from the first and second conductive inserts (120 and 122) to first and second conductive layers (130 and 132) of PCB 116; and ii) sensing the signal using sensor 150.

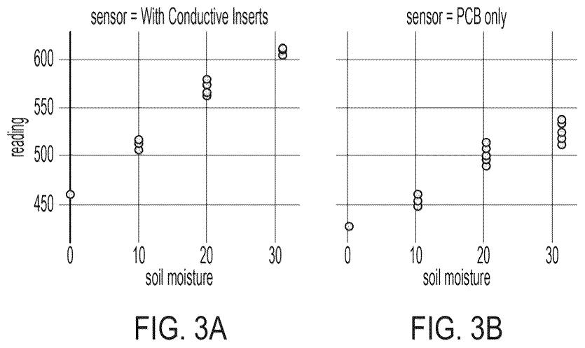

In some embodiments, the presence of conductive inserts 120 and 122 may enhance the sensitivity of the probe to moisture content. This can be appreciated from a comparison of the plots of FIGS. 3A and 3B. FIG. 3A is a plot illustrating a representative reading of a soil probe as a function of soil moisture and in the presence of conductive inserts, FIG. 3B is a plot illustrating a representative reading of a soil probe as a function of soil moisture and in the absence of conductive inserts. In the example of FIG. 3B, conductive layers 130 and 132 of PCB 116 are directly in contact with soil. It should be noted that the values corresponding to the y-axis (the reading) are provided in arbitrary units. As can be appreciated by comparing the plots, the slope of the line that interpolates the data samples associated with FIG. 3A is larger than the slope of the line that interpolates the data samples associated with FIG. 3B. The larger slope indicates a higher sensitivity to moisture content, leading to a greater measurement resolution. The increase in sensitivity may be due at least in part to an increase in the electric field in the area surrounding the probe owing to the greater conductive mass afforded by the conductive inserts. The increased electric field may render the probe less sensitive to soil heterogeneity, resulting in a higher sensitivity to moisture and less measurement variability.

Additionally, or alternatively, the presence of conductive inserts 120 and 122 may reduce the variability of soil moisture measurements, thus improving consistency and accuracy.

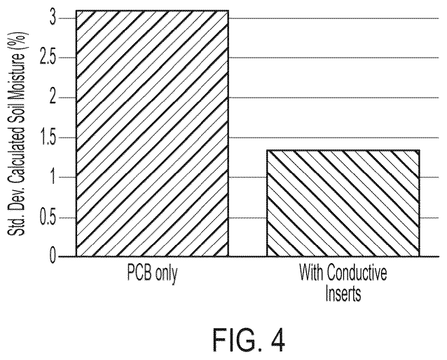

FIG. 4 is a histogram comparing the standard deviation associated with the measured soil moisture obtained using a soil probe not including conductive inserts (labelled “PCB only”) and using a soil probe including conductive inserts (labelled “with conductive inserts”). In this plot, the standard deviation represents the variability of soil measurements. The standard deviation associated with the soil probe not including conductive inserts is in excess of 3%, while the standard deviation associated with the soil probe including conductive inserts is less than 1.5%. In some embodiments, the standard deviation of moisture content measurements obtained using a soil probe described herein is about 3% or less, 2.5% or less, 2% or less, 1.5% or less, or 1% or less. In some embodiments, the standard deviation of moisture content measurements obtained using a soil probe described herein is in a range from 1% to 1.5%, 1% to 2%, 1% to 2.5%, 1% to 3%, 1.5% to 2%, 1.5% to 2.5%, 1.5% to 3%, 2% to 2.5%, 2% to 3%, or 2.5% to 3%.

### IV. Light Sensors

As described in connection with FIG. 2D, probe 100 may include a light sensor 206. Light sensor 206 may sense the amount of ambient light. For example, light may be measured in units of PPFD, a common agricultural standard for measuring light intensity which measures the amount of photons striking an area over time in units of micromoles per square meter per second. Information obtained using this sensor may be transmitted to a user. Using this information, the user may decide whether to make changes to the environment, for example by reorienting a plant towards (or away from) the light source.

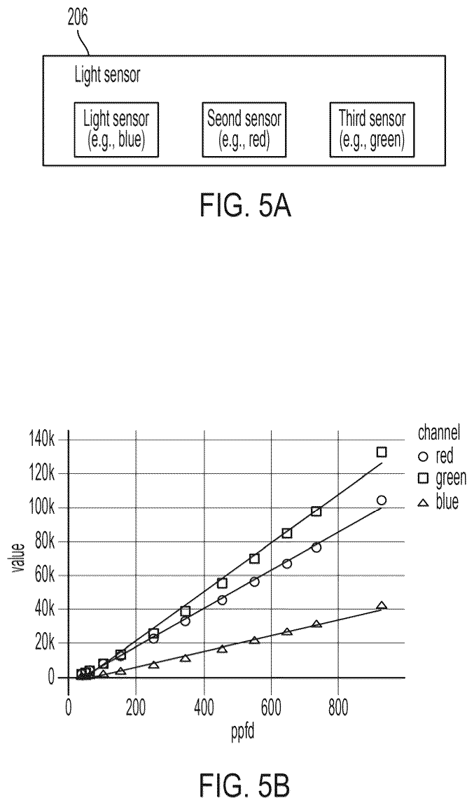

FIG. 5A is a block diagram illustrating an example of a light sensor 206, in accordance with some embodiments. In this implementation, light sensor 206 includes a first sensor, a second sensor and a third sensor, though other numbers of sensors are also possible (e.g., 2, 4, 5, 6, or more sensors). In some embodiments, one or more of the first sensor, second sensor, and third sensor are configured to detect visible light. The first sensor may be designed to capture blue light, the second sensor may be designed to capture red light and the third sensor may be designed to capture green light. Alternative or additional wavelengths are also possible. Although not illustrated, light sensor 206 may further include a fourth sensor designed to capture infrared light and/or a fifth sensor designed to capture ultraviolet light. The multi-spectral nature of light sensor 206 allows conversion of the sensed signal into standard PPFD units using simple linear models. FIG. 5B is a plot representative readings (for red, green and blue channels) of the sensors of FIG. 5A as a function of photosynthetic photon flux density (PPFD). This plot illustrates that the readings of the sensors of FIG. 5A behave linearly with respect to PPFD. The linear behavior allows use of these types of sensors in lieu of more conventional sensors (such as photosynthetically active radiation (PAR) meters), in which linearity comes at the expense of large costs.

In addition, the multi-spectral nature of light sensor 206 can allow for more fine discrimination of the quality of light than can be accomplished with typical conventional light meters fore comparable applications. This can be particularly valuable because it has been shown that different colors of light support different growth phases.

### V. Example Concepts

A1. A soil probe, comprising: a soil penetrating portion comprising: a first printed circuit board (PCB) comprising a first conductive layer and a second conductive layer opposite the first conductive layer; and a first conductive insert electrically coupled to the first conductive layer of the first PCB, and a second conductive insert electrically coupled to the second conductive layer of the first PCB, wherein, when the soil penetrating portion is inserted in soil, both the first and second conductive inserts are configured to contact the soil.

A2. The soil probe of concept A1, further comprising: circuitry electrically coupled to the first and second conductive layers of the first PCB and configured to determine a characteristic of the soil based on a signal appearing between the first and second conductive inserts.

A3. The soil probe of concept A2, wherein the circuitry is configured to determine a moisture content of the soil based on a measure of capacitance formed between the first and second conductive inserts.

A4. The soil probe of concept A2, wherein the circuitry is mounted on the first PCB.

A5. The soil probe of any one of concepts A1-A4, further comprising a second PCB coupled to the first PCB.

A6. The soil probe of concept A5, wherein the second PCB comprises a wireless transmitter.

A7. The soil probe of any one of concept A5-A6, wherein the second PCB is coupled to the first PCB via a Universal Serial Bus (USB) interface.

A8. The soil probe of concept A7, wherein the USB interface is a USB-C interface.

A9. The soil probe of any one of concept A5-A8, wherein the second PCB comprises a light sensor.

A10. The soil probe of concept A9, wherein the light sensor comprises a plurality of sensors, wherein each sensor of the plurality of sensors is configured to sense light at different wavelengths than other sensors of the plurality of sensors.

A11. The soil probe of any one of concepts A5-A10, wherein the second PCB comprises a temperature sensor and/or a humidity sensor.

A12. The soil probe of any one of concepts A1-A11, wherein: the first conductive insert is in physical contact with the first conductive layer of the first PCB, and the second conductive insert is in physical contact with the second conductive layer of the first PCB.

A13. The soil probe of any one of concepts A1-A12, wherein the first and second conductive inserts comprise aluminum, stainless steel and/or conductive polymer.

A14. The soil probe of any one of concepts A1-A13, further comprising: a first conductive component electrically coupling the first conductive insert with the first conductive layer of the first PCB, and a second conductive component electrically coupling the second conductive insert with the second conductive layer of the first PCB.

A15. The soil probe of concept A14, wherein the first and second conductive components comprise an epoxy resin.

A16. The soil probe of any one of concept A1-A15, further comprising a housing comprising the soil penetrating portion and a head portion coupled to the soil penetrating portion, wherein the first PCB is held by the soil penetrating portion of the housing.

A17. The soil probe of concept A16, wherein a second PCB is held by the head portion of the housing.

A18. The soil probe of any one of concepts A1-A17, wherein the first and second conductive inserts are detachable from the soil penetrating portion.

A19. The soil probe of any one of concepts A1-A18, wherein the first conductive insert has a thickness that is between 2 mm and 20 mm.

B1. A method for probing a soil using a soil probe comprising a first printed circuit board (PCB) and first and second conductive inserts, the method comprising: in response to the first and second conductive inserts contacting the soil, determining at least one characteristic of the soil based on a signal appearing between the first and second conductive inserts, wherein determining the characteristic of the soil comprises: transferring the signal from the first and second conductive inserts to first and second conductive layers positioned on opposite sides of the first PCB; and sensing the signal.

B2. The method of concept B1, wherein determining the characteristic of the soil based on the signal appearing between the first and second conductive inserts comprises determining a moisture content of the soil based on a measure of capacitance formed between the first and second conductive inserts.

B3. The method of any one of concepts B1-B2, wherein determining the characteristic of the soil is performed using circuitry mounted on the first PCB.

B4. The method of any one of concepts B1-B3, further comprising wirelessly transmitting information indicative of the characteristic of the soil to an electronic device outside the soil probe.

B5. The method of concept B4, wherein wirelessly transmitting the information is performed using a wireless transmitter positioned on a second PCB coupled to the first PCB.

B6. The method of concept B5, further comprising transferring the information from the first PCB to the second PCB via a Universal Serial Bus (USB) interface.

B7. The method of concept B6, wherein the USB interface is a USB-C interface.

B8. The method of any one of concepts B5-B7, wherein the information is transferred from the first PCB to the second PCB using an I2C communication protocol.

B9. The method of any one of concepts B1-B8, further comprising sensing light using a light sensor positioned on the second PCB.

B10. The method of concept B9, wherein sensing light using the light sensor comprises sensing light at a first wavelength using a first sensor; and sensing light at a second wavelength using a second sensor.

C1. A method for manufacturing a soil probe, comprising: electrically coupling a first conductive insert to a first conductive layer of a first printed circuit board (PCB); electrically coupling a second conductive insert to a second conductive layer of the first printed circuit board (PCB), wherein the second conductive layer is positioned opposite the first conductive layer on the first PCB; and connecting the first and second conductive inserts to a soil penetrating portion so that, when the first and second conductive inserts are electrically coupled to the first and second conductive layers of the first PCB and the soil penetrating portion is inserted in a soil, the first and second conductive inserts are in contact with the soil.

C2. The method of concept C1, further comprising: electrically coupling circuitry to the first and second conductive layers of the first PCB, the circuitry being configured to determine a characteristic of the soil based on a signal appearing between the first and second conductive inserts.

C3. The method of concept C2, wherein the circuitry is configured to determine a moisture content of the soil based on a measure of capacitance formed between the first and second conductive inserts.

C4. The method of any one of concepts C2-C3, wherein electrically coupling the circuitry to the first and second conductive layers comprises mounting the circuitry to the first PCB.

C5. The method of any one of concepts C1-C4, further comprising mounting a wireless transmitter on a second PCB, and coupling the second PCB to the first PCB.

C6. The soil probe of concept C5, wherein coupling the second PCB to the first PCB comprises connecting the second PCB to the first PCB via a Universal Serial Bus (USB) interface.

C7. The soil probe of concept C6, wherein the USB interface is a USB-C interface.

C8. The method of any one of concepts C1-C7, wherein: electrically coupling the first conductive insert to the first conductive layer of the first PCB comprises placing the first conductive insert in physical contact with the first conductive layer of the first PCB, and electrically coupling the second conductive insert to the second conductive layer of the first PCB comprises placing the second conductive insert in physical contact with the second conductive layer of the first PCB.

C9. The method of any one of concepts C1-C8, wherein: electrically coupling the first conductive insert to the first conductive layer of the first PCB comprises placing a first conductive component between the first conductive insert and the first conductive layer of the first PCB, and electrically coupling the second conductive insert to the second conductive layer of the first PCB comprises placing a second conductive component between the second conductive insert and the second conductive layer of the first PCB.

C10. The method of concept C9, wherein the first and second conductive components comprise an epoxy resin.

### VI Conclusion

Having thus described several aspects and embodiments of the disclosed technology, it is to be appreciated that various alterations, modifications, and improvements will readily occur to those of ordinary skill in the art. Such alterations, modifications, and improvements are intended to be within the spirit and scope of the technology described in the application. It is, therefore, to be understood that the foregoing embodiments are presented by way of example only and that, within the scope of the appended claims and equivalents thereto, inventive embodiments may be practiced otherwise than as specifically described. In addition, any combination of two or more features, systems, articles, materials, and/or methods described herein, if such features, systems, articles, materials, and/or methods are not mutually inconsistent, is included within the scope of the present disclosure.

Also, as described, some aspects may be embodied as one or more methods. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

The term “about” may be used to mean within +20% of a target value in some embodiments, within +10% of a target value in some embodiments, within +5% of a target value in some embodiments, and yet within +2% of a target value in some embodiments. The term “about” may include the target value.

What is claimed is:

1. A soil probe, comprising:
a soil penetrating portion comprising:
a first printed circuit board (PCB) comprising a first conductive layer and a second conductive layer opposite the first conductive layer; and
a first conductive insert electrically coupled to the first conductive layer of the first PCB, and a second conductive insert electrically coupled to the second conductive layer of the first PCB, wherein, when the soil penetrating portion is inserted in soil, both the first and second conductive inserts are configured to contact the soil.

2. The soil probe of claim 1, further comprising:
circuitry electrically coupled to the first and second conductive layers of the first PCB and configured to determine a characteristic of the soil based on a signal appearing between the first and second conductive inserts.

3. The soil probe of claim 2, wherein the circuitry is configured to determine a moisture content of the soil based on a measure of capacitance formed between the first and second conductive inserts.

4. The soil probe of claim 2, wherein the circuitry is mounted on the first PCB.

5. The soil probe of claim 1, further comprising a second PCB coupled to the first PCB.

6. The soil probe of claim 5, wherein the second PCB comprises a wireless transmitter.

7. The soil probe of claim 5, wherein the second PCB is coupled to the first PCB via a Universal Serial Bus (USB) interface.

8. The soil probe of claim 5, wherein the second PCB comprises a light sensor.

9. The soil probe of claim 8, wherein the light sensor comprises a plurality of sensors, wherein each sensor of the plurality of sensors is configured to sense light at different wavelengths than other sensors of the plurality of sensors.

10. The soil probe of claim 5, wherein the second PCB comprises a temperature sensor and/or a humidity sensor.

11. The soil probe of claim 1, wherein:
the first conductive insert is in physical contact with the first conductive layer of the first PCB, and
the second conductive insert is in physical contact with the second conductive layer of the first PCB.

12. The soil probe of claim 1, further comprising:
a first conductive component electrically coupling the first conductive insert with the first conductive layer of the first PCB, and
a second conductive component electrically coupling the second conductive insert with the second conductive layer of the first PCB.

13. The soil probe of claim 1, further comprising a housing comprising the soil penetrating portion and a head portion coupled to the soil penetrating portion, wherein the first PCB is held by the soil penetrating portion of the housing.

14. The soil probe of claim 13, wherein a second PCB is held by the head portion of the housing.

15. The soil probe of claim 1, wherein the first and second conductive inserts are detachable from the soil penetrating portion.

16. The soil probe of claim 1, wherein the first conductive insert has a thickness that is between 2 mm and 20 mm.

17. A method for probing a soil using a soil probe comprising a first printed circuit board (PCB) and first and second conductive inserts, the method comprising:
in response to the first and second conductive inserts contacting the soil, determining at least one characteristic of the soil based on a signal appearing between the first and second conductive inserts, wherein determining the characteristic of the soil comprises:
transferring the signal from the first and second conductive inserts to first and second conductive layers positioned on opposite sides of the first PCB; and
sensing the signal.

18. The method of claim 17, wherein determining the characteristic of the soil based on the signal appearing between the first and second conductive inserts comprises determining a moisture content of the soil based on a measure of capacitance formed between the first and second conductive inserts.

19. The method of claim 17, wherein determining the characteristic of the soil is performed using circuitry mounted on the first PCB.

20. The method of claim 17, further comprising wirelessly transmitting information indicative of the characteristic of the soil to an electronic device outside the soil probe.

21. The method of claim 20, wherein wirelessly transmitting the information is performed using a wireless transmitter positioned on a second PCB coupled to the first PCB.

22. The method of claim 21, further comprising transferring the information from the first PCB to the second PCB via a Universal Serial Bus (USB) interface.

23. The method of claim 17, further comprising sensing light using a light sensor positioned on the second PCB.

24. The method of claim 23, wherein sensing light using the light sensor comprises:
sensing light at a first wavelength using a first sensor; and
sensing light at a second wavelength using a second sensor.
